(19) United States
(12) Patent Application Publication
(10) Pub. No.: US 2004/0259348 A1
(43) Pub. Date: Dec. 23, 2004

(54) Method of reducing post-CMP defectivity

(76) Inventors: Bulent M. Basol, Manhattan Beach, CA (US); Homayoun Talieh, San Jose, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 10/818,976

(22) Filed: Apr. 6, 2004

Related U.S. Application Data
(63) Continuation-in-part of application No. 09/795,687, filed on Feb. 27, 2001.

(51) Int. Cl. H01L 21/20; H01L 21/4763

(52) U.S. Cl. 438/622; 438/626; 438/638

(57) ABSTRACT

In one aspect of the present invention, a method of forming substantially planar conductive structures in cavities on a surface of a workpiece is provided. The method initially forms a large grain layer to overfill the cavities. A small grain conductive layer is formed on the large-grain layer. The small-grain layer has a second material removal rate which is lower than the first material removal rate. During the removal process, the small-grain layer is partially removed so that a small-grain layer portion remains in the recessed portions of the large-grain layer. In the following step, the large-grain layer is continued to be removed at the first material removal rate while the second layer portion is removed at the second material removal rate until the planar conductive structures are formed in the cavities.

### RELATED APPLICATIONS

This application is a continuation in part of U.S. patent Ser. No. 09/795,687 filed Feb. 27, 2001 (NT-202) incorporated herein by reference.

### FIELD

The present invention relates to manufacture of semiconductor integrated circuits and, more particularly to a method of fabricating interconnect structures with reduced defectivity.

### BACKGROUND

Conventional semiconductor devices generally include a semiconductor substrate, such as a silicon substrate, and a plurality of sequentially formed dielectric interlayers such as silicon dioxide and conductive paths or interconnects made of conductive materials. Copper and copper-alloys have recently received considerable attention as interconnect materials because of their superior electro-migration and low resistivity characteristics. Interconnects are usually formed by filling copper in features or cavities etched into the dielectric layers by a metallization process. The preferred method of copper metallization is electroplating. In an integrated circuit, multiple levels of interconnect networks laterally extend with respect to the substrate surface. Interconnects formed in sequential layers can be electrically connected using vias.

In a typical process, first an insulating layer is formed on the semiconductor substrate. Patterning and etching processes are performed to form features or cavities such as trenches and vias in the insulating layer. Then, a barrier/glue layer and a seed layer are deposited over the patterned surface and a conductor such as copper is electroplated to fill all the features.

FIG. 1 illustrates a substrate 10 representing a portion of a semiconductor wafer surface that is electrochemically plated with a conductive metal such as copper 11. The electroplated substrate includes a dielectric layer 12, which has features 14 and 16 formed in the dielectric layer. Before the electrochemical copper plating, surface 18 of the dielectric (field region), including inner surfaces of the features 14, 16, are lined with a barrier layer 20 which is also coated with a copper seed layer (not shown). In this example, the features 14 are small size trenches or vias that are grouped as high-density features while the feature 16 represents a medium or large size trench. The width of small features 14 in this example may be less than 1 micron, and the width of the large trench may be more than 10 microns. The depth of the features may be in the range of 0.2-6 microns. The plating process, in addition to filling the features with copper, also deposits excess copper 22 over the surface 18 of the dielectric. The excess copper 22 is called an “overburden” and needs to be removed during a subsequent process step. In standard plating processes, this overburden copper has a large step ‘S’ since an Electrochemical Deposition (ECD) process coats large features on the wafer in a conformal manner. Conventionally, after the copper plating, chemical mechanical polishing (CMP) process is employed to planarize the topographic surface depicted in FIG. 1, and to reduce the thickness of the overburden copper layer down to the level of the surface of the barrier layer, which is shown with dotted line. The barrier layer portion on the surface 18 is also later removed leaving copper and barrier only in the cavities.

Before the CMP process, an anneal step is typically performed to enlarge and stabilize the grains of the copper layer 11. As shown in FIG. 2, with the annealing process, large grains 24 are formed in the copper layer 11. For example, as-deposited grain size for typical electroplated copper layers is smaller than 0.2 microns, whereas after annealing either at elevated temperatures or at room temperature, the grain size increases to above 0.5 microns. It has been experimentally seen that copper layers with large grains are polished at a higher rate than copper layers with small grains. Therefore, layers with larger grains are removed more easily and quickly by the CMP process in comparison to layers with smaller grains. It should be noted that same arguments may apply to the more recently developed copper overburden removal techniques such as electrochemical mechanical polishing (ECMP) where an anodic voltage is applied to the copper layer with respect to an electrode which is in electrical communication with the copper layer through a process solution or slurry during the polishing process.

Since the standard process flow involves annealing the copper layer after electroplating, a large grain structure is formed as shown in FIG. 2. When this large grain structure is subjected to the CMP or ECMP process, copper is planarized and removed at substantially the same rate over the substrate. However, as illustrated in FIG. 3A, when copper is cleared from most of the field region 18, there is typically a residual copper layer 26 remaining over the dense features 14 because copper thickness of the overburden layer over the dense features is typically larger. The residual copper 26 must be removed to avoid electrical shorts between the copper-filled regions in small features. This removal is performed by carrying out an over-polishing process for a set period of time, which may be 5-30% of the CMP time. However, such over-polishing causes dishing 28, which is excessive, in the large trench as shown in FIG. 3B. Dishing defects cause problems in multi-layer interconnect fabrication and increase the resistance of the fabricated copper lines. Therefore, there is a need to minimize or eliminate dishing over large features. For medium size dense features, there is also the well known problem of erosion which also gives rise to metal loss. It should be noted that for brevity, the invention will be described in terms of avoiding dishing. However, the invention is also effective in avoiding or reducing erosion over medium size dense features.

### SUMMARY

Present invention reduces the effective removal rate of copper selectively at regions with large features. This is provided by forming a composite overburden structure to change material removal characteristics of the overburden layer. In one embodiment, the composite overburden structure includes a first and a second layer having different grain sizes and thus different material removal rates. As the first and the second layer are exposed to the same material removal process, one layer may be removed faster than the other.

In one aspect of the present invention, a method of forming substantially planar conductive structures in cavities on a surface of a workpiece is provided. The method initially includes the step of depositing a first layer of a conductive material to overfill the cavities. The first layer includes recessed portions above the cavities and raised portions between the cavities. In the following step, the first layer is transformed into a large-grain layer, which has a first material removal rate, by annealing the first layer. In the following step, a second layer of the conductive material is deposited onto the large-grain layer. The second layer has a second material removal rate which is lower than the first material removal rate. In the following step, the second layer is partially removed so that a second layer portion remains in the recessed portions of the large-grain layer. In the following step, the large-grain layer is continued to be removed at the first material removal rate and the second layer portion is removed at the second material removal rate until the planar conductive structures are formed in the cavities.

Another aspect of the present invention provides a method of forming substantially planar conductive structures in cavities on a surface of a workpiece. The method initially includes the step of depositing a first layer of a conductive material to partially fill the cavities. The first layer includes recessed portions extending into the cavities and raised portions between the cavities. In the following step, first layer is transformed into a large-grain layer, which has a first material removal rate, by annealing the first layer. In the following step, a second layer of the conductive material is deposited onto the large-grain layer. The second layer has a second material removal rate which is lower than the first material removal rate. In the following step, the second layer is partially removed so that a second layer portion remains in the recessed portions of the large-grain layer. In the following step, the large-grain layer is continued to be removed at the first material removal rate and the second layer portion is removed at the second material removal rate until planar conductive structures are formed in the cavities.

Yet another aspect of the present invention provides a method of forming substantially planar conductive structures in cavities on a surface of a workpiece. The cavities include a first cavity and a second cavity, and the first cavity is wider than the second cavity. The method initially includes the step of depositing a first layer of a conductive material to overfill the cavities. The first layer has recessed portion over the first cavity and a raised portion over the second cavity. The first layer is transformed into a large-grain layer, which has a first material removal rate, by annealing the first layer. In the following step, a second layer of the conductive material is deposited onto the large-grain layer. The second layer has a second material removal rate which is lower than the first material removal rate. In the following step, the second layer is partially removed so that a second layer portion remains in the recessed portion of the large-grain layer. In the following step, the large-grain layer is continued to be removed at the first material removal rate and the second layer portion is removed at the second material removal rate until the planar conductive structures are formed in the cavities.

These and other features and advantages of the present invention will be described below with reference to the associated drawings.

### BRIEF DESCRIPTION OF THE DRAWINGS

FIG. 1 is a schematic illustration of a prior art substrate having features in it, wherein a conducive layer has been deposited on the substrate;

FIG. 2 is a schematic illustration of the prior art substrate, wherein an anneal process has been applied to enlarge the grains of the conductive layer;

FIG. 3A-3B is a schematic illustrations of the substrate shown in FIG. 2, wherein polishing of the conductive layer causes dishing of the conductive layer in the large feature;

FIG. 4 is a schematic illustration of a substrate of the present invention having a large grain layer forming a recessed portion above the large feature and raised portion elsewhere, wherein a planar small grain layer has been deposited on the large grain layer;

FIG. 5A is a schematic illustration of the substrate shown in FIG. 4, wherein the small grain layer has been removed from raised portions of the large grain layer and left in the recessed portions of the large grain layer;

FIG. 5B is a schematic top view of the substrate shown in FIG. 5A;

FIG. 6 is a schematic illustration of the substrate shown in FIG. 5A, wherein the small grain layer has been delayed the planarization of the large grain layer over the large feature;

FIGS. 7-8 are schematic illustrations of further planarization of the large grain layer shown in FIG. 6;

FIGS. 9-11 are schematic illustration of another embodiment of the present invention; and

FIGS. 12A-12B are schematic illustrations of an alternative embodiment of the present invention.

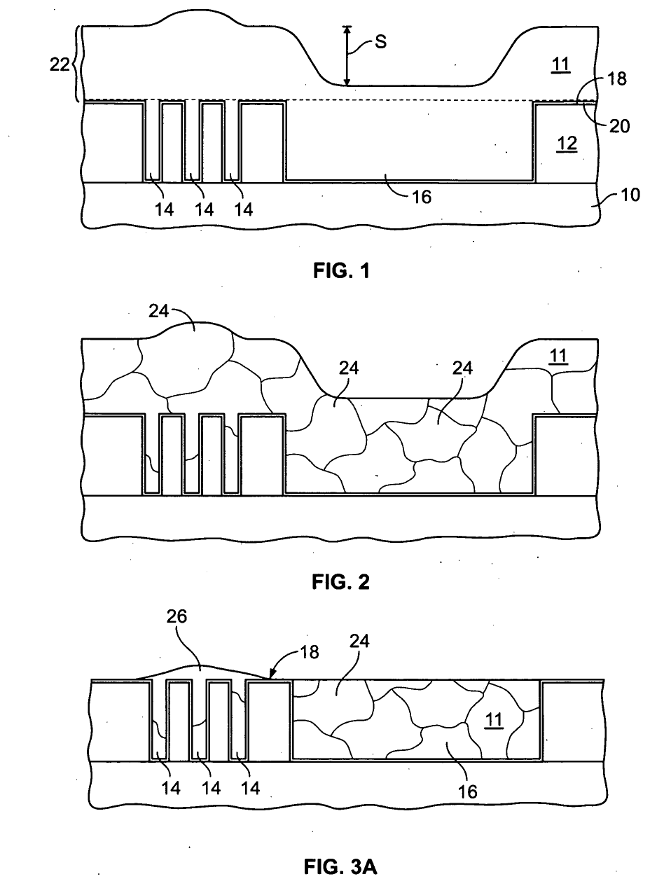

### DETAILED DESCRIPTION

Present invention provides a method that reduces the effective removal rate of copper selectively at regions with large features. This way, excessive dishing into the large features is avoided when the high-density regions with small features are over-polished to clear any copper residue. The process of the present invention first forms a composite overburden structure to change material removal characteristics of the overburden layer and thereby preventing dishing and erosion in chemical mechanical or electrochemical mechanical polishing step. In one embodiment, the composite overburden structure is comprised of a first and a second layer having different grain sizes and thus different material removal rates. When layers with different removal rates are exposed to the same material removal process, one layer may be removed faster than the other.

In one embodiment the composite overburden may be formed on a wafer having features, with a process using an electrochemical deposition step to form the first layer, an anneal step to enlarge the grains in the first layer and an electrochemical mechanical deposition step to form the second layer with small grains on the first layer. The first layer forms a conformal overburden layer over large features, which are prone to excessive dishing during the CMP step. The first layer may also form a near-conformal overburden layer over medium size dense features that are prone to erosion, however, invention will be described using as an example a portion of a wafer with small and large features only. The annealing step transforms the first layer into a large grain copper layer. The electrochemical mechanical deposition step forms the second layer with small grains on the large-grain first layer. The second layer may be a substantially planar layer and thus forms a film with varying thickness on the first layer, with thicker sections over the large features and thinner portions over the neighboring raised sections. This way, more small-grained material is deposited over the large features that are most prone to dishing defects, and less small-grained material is deposited in regions that do not need to be protected by the small removal rate of the small grain material.

After deposition of the second layer, the overburden removal process is carried out without any annealing step and before the grains in the second layer grows to the size of the grains in the first layer. This way small grain portions of the second layer over the large features reduce material removal rate on the large features during the CMP step. Presence of thick small-grain material selectively in those areas delays copper polishing over the large features and thereby prevents dishing as will be described next.

FIG. 4 shows a multilayer substrate 100 having a composite overburden 102 comprising a first layer 104 and a second layer 106, which may be obtained by depositing a substantially planar second layer on the structure depicted in FIG. 2. The first layer 104 is formed on a dielectric layer 108, which is formed on a semiconductor 110. The second layer 106 is formed onto surface 109 of the first layer 104 after annealing the first layer 104 and increasing its grain size. In this embodiment, the first and second layers 104, 106 are copper layers, and the multilayer substrate 100 may be a portion of a semiconductor wafer. The dielectric layer 108 has features 112 and 114 as components of an interconnect structure. The features 112 are high aspect ratio (depth-to-width ratio) small features, such as narrow trenches with aspect ratios of larger than 1.0. In FIG. 4, the narrow trenches 112 are grouped to establish a high-density feature area on the substrate. The feature 114 may be a large trench or bond pad with a low aspect ratio such as an aspect ratio less than 0.1. The features 112, 114 and surface 116 of the dielectric layer are lined with a barrier layer 118 such as Ta or TaN layer. As it is typical for copper electrodeposition, a copper seed layer is also coated onto the barrier layer 118, but for clarity, this layer is not shown in the drawings.

The first layer 104 has recessed portions 120 and raised portions 122, which are formed during the deposition of the first layer 104. The first layer 104 is deposited using an electrochemical deposition (ECD) process and its thickness may be equal to, less than or more than the depth of the features, but preferably more than the depth of the features. Typically, thickness of the first layer is 1.2-1.5 times the depth of the features. After the deposition, the first layer 104 is annealed to enlarge its grains 124. The annealing process may be performed in a temperature range of 90-500° C. for a period of 5 seconds to 5 hours, which allows grains 124 to grow approximately to a size that is equal to or larger than the thickness of the first layer. It is well known that, grain growth in the first layer may also be obtained by self-annealing process, which involves leaving the films at room temperature for a few hours or a few days depending upon the impurities in the film and the plating conditions. It is, however, preferable to anneal the films at elevated temperatures to achieve grain growth in a shorter time.

The second layer 106 is preferably deposited using an electrochemical mechanical deposition process (ECMPR). An exemplary ECMPR system is described below. It should be noted that, for features with widths in the 5-10 micron range, it would be possible to obtain substantially planar layers using the ECD technique, provided that organic additives in the plating electrolyte is optimized to yield some degree of bottom-up growth or super-fill in such features. For example, in such electrolytes the accelerator additive may be present at a higher than normal level. However, for features much larger than 10 microns in width, ECMD process is the preferred method of forming a substantially planar second layer. Therefore, the invention will be described using ECMD as the method for depositing the second layer. Grains 126 of the second layer 106 are smaller than the grains 124 of the first layer, which has been annealed. Therefore, the removal rate of the second layer is lower than the removal rate of the first layer. For example, the removal rate of the small grained layer may be in the 2000-6000 A/min range, whereas, the removal rate of the annealed layer may be in the 5000-10000 A/min. As seen in FIG. 4 the second layer 106 fills the recessed portion 120 and coats the raised portions 122 of the first 104. Once the deposition of the second layer 106 is complete, the thickness of the second layer at the recessed portion is higher than the thickness of the second layer at raised portions. In other words, recessed portions 120 are filled with a thick copper layer with small grain size. This is attractive because if the thickness of the second layer over the raised portions were the same as the thickness of the second layer at the recessed portion, it would take a long time to polish off the second layer from over the raised portions and this would reduce the throughput of the process.

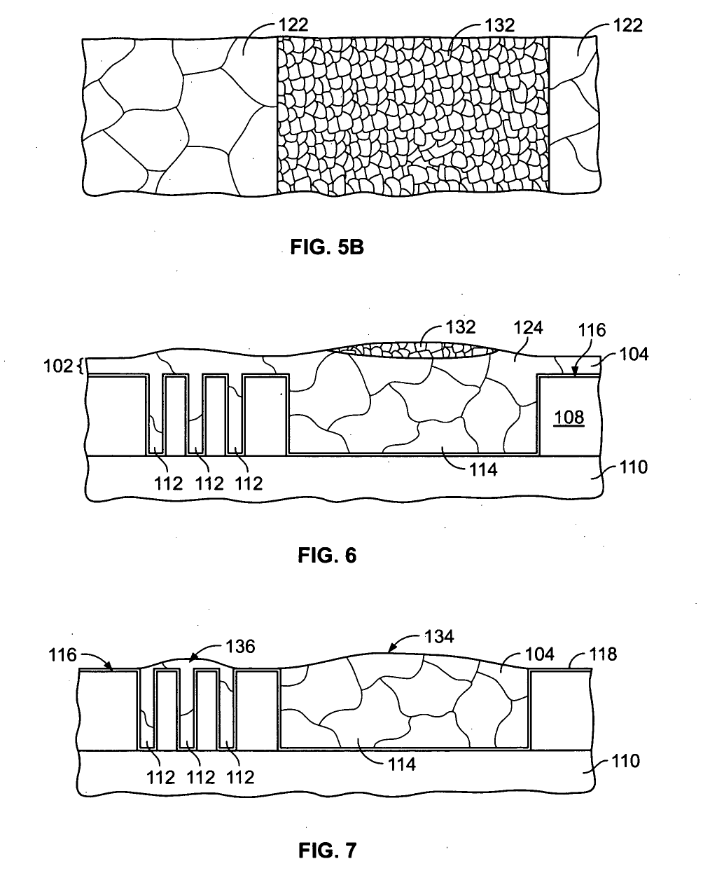

As the CMP process is applied to the structure shown in FIG. 4, copper removal rate from the top surface of the second layer would be uniform and low until the raised portions 122 of the first layer 104 are exposed, exposing the large grain material to the CMP environment. The resulting structure after the initial CMP step is exemplified in FIG. 5A in side view and in FIG. 5B in top view, where a second layer portion 132 with small grains is selectively formed within a matrix of first layer with large grains. This is achieved by removing the thin portions of the second layer 106 from the raised portions 122. The second layer portion 132 is confined on the recessed portion 120 of the first layer 104. The second layer portion 132 will be referred to as slow-polish portion below. The slow-polish portion 132 slows down the polishing rate over the feature 16 and allows polishing process to advance towards neighboring first layer.

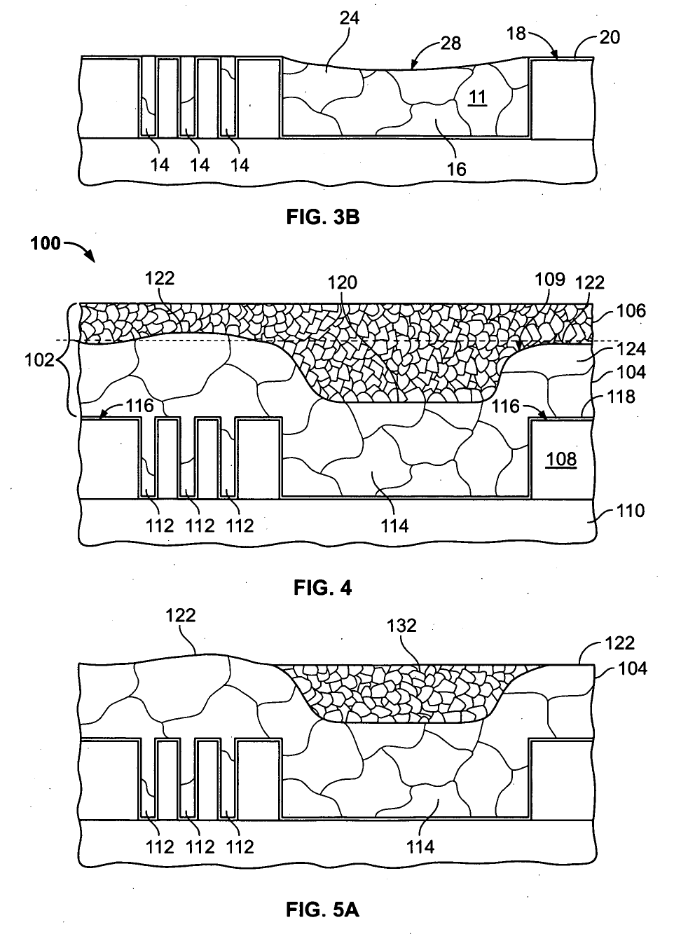

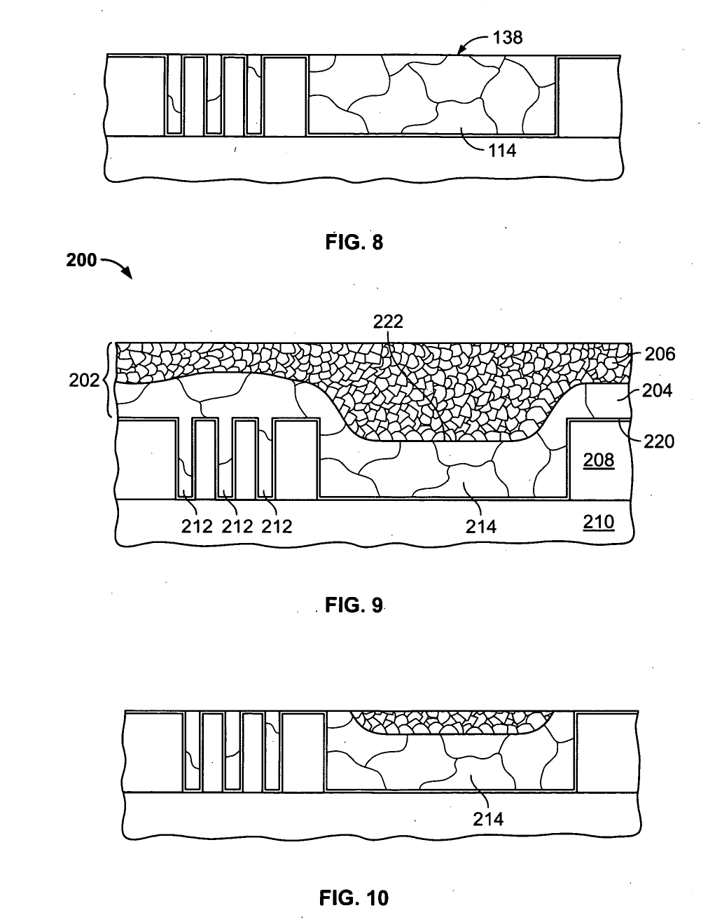

As shown in FIG. 6, as the polishing of the overburden 102 advances towards the surface 116 of the dielectric, lower removal rate of the slow-polish portion 132 versus higher removal rate of neighboring first layer 104 changes the profile of the overburden layer 102. As exemplified in FIG. 7, due to the delay in material removal rate provided by the slow-polish portion 132, as the barrier layer is exposed on surface 116, an excess copper bump 134 is formed over the large feature along with a residual copper film 136 over the dense features 112. As will be appreciated this structure is quite different from the prior art structure shown in FIG. 3A. As described above, in prior art polishing techniques over-polishing, which is applied for the removal of residual metal from over dense features, causes dishing problem in the neighboring large features. However, in this embodiment of the present invention, the bump 134 left over the large feature 114 prevents dishing problems. As the residual copper 136 is over-polished, the excess copper bump 134 is also polished down. As shown in FIG. 8, this results in a flat copper surface 138, which is substantially planar, over the whole surface including the large feature 114.

FIG. 9 shows another embodiment of the present invention. In FIG. 9, a multi-layer substrate 200 has composite overburden 202 comprising a first layer 204 and a second layer 206. In this embodiment, the first and second layers 204, 206 are also copper layers and they are deposited using the same processes used for the first and second layer described before. The difference from the previous embodiment is the fact that in this embodiment, the first layer does not entirely fill the large feature 214. A recessed portion 222 of the first layer penetrates into the large feature 214.

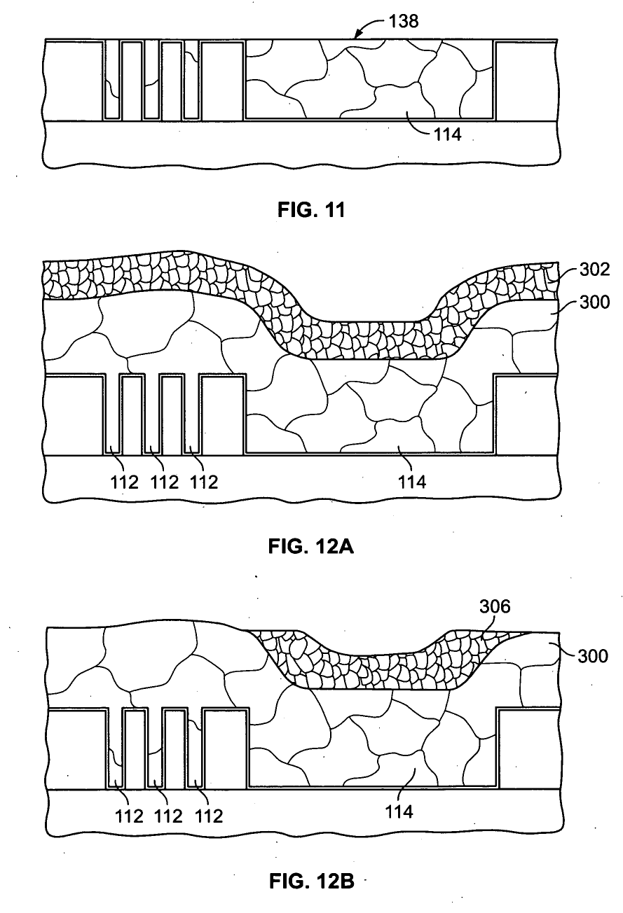

After deposition, the first layer is annealed to enlarge its grains. The second layer with small grains is then deposited onto the raised portions 224 and the recessed portion 222 of the first layer having large grains. The second layer is preferably deposited using an electrochemical mechanical deposition process to form a substantially planar layer on the first layer, which is a conformal layer in this embodiment. In the following CMP step, as shown in FIG. 10, the composite overburden layer 202 is completely planarized down to the barrier layer 220. During CMP, lower material removal rate of second layer with small grains prevents dishing just like in FIG. 8. After the planarization, however, an annealing step may be needed to transform the remaining second layer into large grains, which is shown in FIG. 11.

In the above embodiments, second layer is preferably deposited using Electrochemical Mechanical Processing (ECMPR), which is a technique that can reduce or totally eliminate copper surface topography for all feature sizes. This process has the ability to eliminate steps and provide thin layers of planar conductive material on the workpiece surface, or even provide a workpiece surface with no or little excess conductive material. The term “Electrochemical Mechanical Processing (ECMPR)” is used to include both Electrochemical Mechanical Deposition (ECMD) processes as well as Electrochemical Mechanical Etching (ECME), which is also called Electrochemical Mechanical Polishing (ECMP), or their combinations. It should be noted that in general both ECMD and ECME processes are referred to as electrochemical mechanical processing (ECMPR) since both involve electrochemical processes and mechanical action on the workpiece surface. The mechanical action can be provided by sweeping the substrate surface with a workpiece-surface-influencing device (WSID) such as a sweeper, pad, blade or wand. The WSID may be porous or may have openings, which allow a process solution to flow between the substrate surface and an electrode during the ECMPR.

Descriptions of various ECMPR systems and processes, can be found in the following exemplary patents and pending applications, all commonly owned by the assignee of the present invention: U.S. Pat. No. 6,176,992 entitled “Method and Apparatus for Electrochemical Mechanical Deposition,” U.S. Pat. No. 6,354,116 entitled “Plating Method and Apparatus that Creates a Differential Between Additive Disposed on a Top Surface and a Cavity Surface of a Workpiece Using an External Influence,” U.S. Pat. No. 6,471,847 entitled “Method for Forming Electrical Contact with a Semiconductor Substrate” and U.S. Pat. No. 6,610,190 entitled “Method and Apparatus for Electrodeposition of Uniform Film with Minimal Edge Exclusion on Substrate. “U.S. Application with Ser. No. 09/960,236 filed on Sep. 20, 2001, entitled “Mask Plate Design”, and U.S. application Ser. No. 10/155,828 filed on May 23, 2002 entitled “Low Force Electrochemical Mechanical Processing Method and Apparatus.” These methods can deposit metals in and over feature sections on a wafer in a planar manner.

Although the preferred method of deposition for the second layer is ECMPR since it yields thicker regions of small-grain material over the features that are prone to dishing, it is possible to exercise the invention using second layers deposited by other methods. As shown in FIG. 12A, after annealing a first layer 300 and enlarging its grains, a second layer 302 may be deposited to obtain a small grain material. Electrodeposition, vapor phase deposition such as evaporation or sputtering, electroless deposition or the like may be used for this deposition step. As it will be appreciated, as polishing is initiated and the small grain material over the top surface is planarized down, a slow-polish portion 306 is formed over large feature 114 as shown in FIG. 12B. Polishing process then is continued as in FIGS. 6 and 7 to achieve the result shown in FIG. 8. Deposition, removal and annealing steps of the present invention may be carried out in an integral process system including ECMD and ECMP chambers, annealing chamber, CMP chamber as well as ECD chamber. Various examples of such integral systems that can be used with the present invention are described in co-pending U.S. patent application Ser. No. 09/795,687 filed Feb. 27, 2001, which is owned by the assignee of the present application.

Although various preferred embodiments and the best mode have been described in detail above, those skilled in the art will readily appreciate that many modifications of the exemplary embodiment are possible without materially departing from the novel teachings and advantages of this invention.

We claim:

1. A method of forming substantially planar conductive structures in cavities on a surface of a workpiece, the method comprising:
depositing a first layer of a conductive material to overfill the cavities, wherein the first layer comprises recessed portions above the cavities and raised portions between the cavities;
transforming the first layer into a large-grain layer having a first material removal rate by annealing the first layer;
depositing a second layer of the conductive material onto the large-grain layer, the second layer having a second material removal rate which is lower than the first material removal rate;
removing the second layer partially so that a second layer portion remains in the recessed portions of the large-grain layer; and
continuing removing the large-grain layer at the first material removal rate and the second layer portion at the second material removal rate until the planar conductive structures are formed in the cavities.

2. The method of claim 1, wherein the step of depositing the second layer comprises depositing a small-grain material layer onto the large-grain layer.

3. The method of claim 2, wherein the small-grain material layer is a planar layer.

4. The method of claim 2, wherein the small-grain material layer comprises recessed portions above the cavities and raised portions between the cavities.

5. The method of claim 1, wherein at least one of the steps of removing comprises chemical mechanical polishing.

6. The method of claim 1, wherein at least one of the steps of removing comprises electrochemical mechanical polishing.

7. The method of claim 1, further comprising the step of forming a barrier layer and a seed layer on the surface of the wafer including the cavities before the step of depositing the first layer.

8. The method of claim 7, wherein the first layer is deposited onto the seed layer.

9. The method of claim 7 further comprising the step of removing the barrier layer such that the barrier layer is left only in the cavities.

10. The method of claim 9, wherein the step of removing the barrier layer comprises chemical mechanical polishing.

11. The method of claim 1, wherein the conductive material is copper.

12. A semiconductor device manufactured using the method of claim 1.

13. A method of forming substantially planar conductive structures in cavities on a surface of a workpiece, the method comprising:
depositing a first layer of a conductive material to partially fill the cavities, wherein the first layer comprises recessed portions extending into the cavities and raised portions between the cavities;
transforming the first layer into a large-grain layer having a first material removal rate by annealing the first layer;
depositing a second layer of the conductive material onto the large-grain layer, the second layer having a second material removal rate which is lower than the first material removal rate;
removing the second layer partially so that a second layer portion remains in the recessed portions of the large-grain layer; and
continuing removing the large-grain layer at the first material removal rate and the second layer portion at the second material removal rate until planar conductive structures are formed in the cavities.

14. The method of claim 13 further comprising the step of annealing the planar conductive structures to obtain large-grain planar conductive structures.

15. The method of claim 13, wherein the step of depositing the second layer comprises depositing a small-grain material layer onto the large-grain layer.

16. The method of claim 15, wherein the small-grain material layer is a planar layer.

17 The method of claim 15, wherein the small-grain material layer comprises recessed portions above the cavities and raised portions between the cavities.

18. The method of claim 13, wherein at least one of the steps of removing comprises chemical mechanical polishing.

19. The method of claim 13, wherein at least one of the steps of removing comprises electrochemical mechanical polishing.

20. The method of claim 13 further comprising the step of forming a barrier layer and a seed layer on the surface of the wafer including the cavities before the step of depositing the first layer.

21. The method of claim 20, wherein the first layer is deposited onto the seed layer.

22. The method of claim 20 further comprising the step of removing the barrier layer such that the barrier layer is only left in the cavities.

23. The method of claim 22, wherein the step of removing the barrier layer comprises chemical mechanical polishing.

24. The method of claim 13, wherein the conductive material is copper.

25. A semiconductor device manufactured using the method of claim 13.

26. A method of forming substantially planar conductive structures in cavities on a surface of a workpiece, the cavities including a first cavity and a second cavity, wherein the first cavity is wider than the second cavity, the method comprising:
depositing a first layer of a conductive material to overfill the cavities, the first layer having a recessed portion over the first cavity and a raised portion over the second cavity;
transforming the first layer into a large-grain layer having a first material removal rate by annealing the first layer;
depositing a second layer of the conductive material onto the large-grain layer, the second layer having a second material removal rate which is lower than the first material removal rate;
removing the second layer partially so that a second layer portion remains in the recessed portion of the large-grain layer; and
continuing removing the large-grain layer at the first material removal rate and the second layer portion at the second material removal rate until the planar conductive structures are formed in the cavities.

27. The method of claim 26, wherein the step of depositing the second layer comprises depositing a small-grain material layer onto the large-grain layer.

28. The method of claim 27, wherein the small-grain material layer is a substantially planar layer.

29. The method of claim 27, wherein the small-grain material layer comprises a recessed portion above the first cavity and a raised portion above the second cavity.

30. The method of claim 26, wherein at least one of the steps of removing comprises chemical mechanical polishing.

31. The method of claim 26, wherein at least one of the steps of removing comprises electrochemical mechanical polishing.

32. The method of claim 26 further comprising the step of forming a barrier layer and a seed layer on the surface of the wafer including the cavities before the step of depositing the first layer.

33. The method of claim 32, wherein the first layer is deposited onto the seed layer.

34. The method of claim 32 further comprising the step of removing the barrier layer such that the barrier layer is left only in the cavities.

35. The method of claim 34, wherein the step of removing the barrier layer comprises chemical mechanical polishing.

36. The method of claim 26, wherein the conductive material is copper.

37. A semiconductor device manufactured using the method of claim 26.
